(19) United States
(12) Patent Application Publication
(10) Pub. No.: US 2005/0275480 A1
(43) Pub. Date: Dec. 15, 2005

(54) Frequency selective oscillator, electronic instrument implementing the same, and method of adjusting frequency control characteristics

(76) Inventor: Shinji Nishio, Suwa-shi (JP)

Correspondence Address: HARNESS, DICKEY & PIERCE, P.L.C., P.O. BOX 828, BLOOMFIELD HILLS, MI, 48303, US

(21) Appl. No.: 11/094,830

(22) Filed: Mar. 30, 2005

(30) Foreign Application Priority Data
Apr. 2, 2004 (JP) 2004-109693
Apr. 2, 2004 (JP) 2004-109697
Apr. 7, 2004 (JP) 2004-113129

(51) Int. Cl. H03B 5/30

(52) U.S. Cl. 331/158

(57) ABSTRACT

A frequency selective oscillator including: a plurality of piezoelectric elements having oscillation frequencies that are different from each other; a plurality of switching sections provided to the plurality of piezoelectric elements at both a signal input side and a signal output side of each of the plurality of piezoelectric elements for synchronously selecting either one of the plurality of piezoelectric elements; and a positive feedback oscillation loop circuit for oscillating one of the plurality of piezoelectric elements selected with the plurality of switching sections.

### BACKGROUND OF THE INVENTION

1. Technical Field

The present invention relates to a frequency selective oscillator outputting a frequency signal corresponding to a piezoelectric element selected from a plurality of piezoelectric elements, an electronic instrument implementing the frequency selective oscillator, and a method of adjusting frequency control characteristics.

2. Related Art

In communication devices such as mobile phones or optical fiber communication systems, communications of transmission data are executed based on clock signals from oscillators. In some of the optical fiber systems, a plurality of signals of different frequencies is used for coping with transmission data having different data structures. In, for example, SONET optical fiber communication systems in the United States, since four frequencies, specifically 622.08 MHz, 644.53125 MHz, 666.51429 MHz, and 669.32658 MHz, are used, high frequency oscillators corresponding to the respective frequencies are required. Therefore, a voltage controlled oscillator having a plurality of piezoelectric elements to output a signal of either one of the different frequencies has been proposed.

The oscillator outputting a plurality of signals of different frequencies is disclosed in Japanese unexamined patent publication No. 2002-335127 and No. 2002-359521. The oscillator disclosed in the former one, Japanese unexamined patent publication No. 2002-335127, selectively operates one of a plurality of crystal oscillators having different frequencies, and selects the harmonic component of the crystal oscillator in operation by a surface wave filter to complementarily output it with the amplified harmonic component. Further, the oscillator disclosed in the latter document, Japanese unexamined patent publication No. 2002-359521, is composed of a plurality of resonance circuits, oscillation transistors, and a plurality of bias circuits, in which one of the bias circuits is selected in accordance with a required oscillation frequency, and one of the resonance circuits is supplied with power via the selected bias circuit, thus operating the resonance circuit.

If the oscillator is composed of a plurality of piezoelectric elements to be formed as a voltage controlled oscillator which outputs a signal with either one of the different frequencies, it is preferable that the frequency control characteristics of respective piezoelectric elements, which are relationships between control voltages to be applied to the piezoelectric elements and frequency variations of the piezoelectric elements, are the same.

However, if a plurality of piezoelectric elements is provided to an oscillator with one of the piezoelectric elements and another of the piezoelectric elements consistently connected to each other, isolation between the piezoelectric elements is not ensured, thus problematically mutually affecting the frequency control characteristics of each other. Further, if a plurality of piezoelectric elements and a single oscillation circuit common to the plurality of piezoelectric elements are provided, the common oscillation circuit causes problems of affecting the oscillation frequency and the frequency control characteristics of the selected piezoelectric element, and of placing limitations in adjusting the frequency control characteristics for each of the piezoelectric elements. Still further, if the frequency control characteristics of the respective piezoelectric elements are different from each other, the frequency control characteristics differing for the piezoelectric elements should problematically be adjusted by a circuit subsequently connected to the oscillator implementing the piezoelectric elements.

Further, since a plurality of piezoelectric oscillators are provided, in other words, the oscillation amplifier is provided to each of the piezoelectric vibrating elements in the oscillator of Japanese unexamined patent publication No. 2002-335127, the circuit scale of the overall oscillator problematically becomes large and the cost of the piezoelectric oscillators problematically increases. Since the circuit for oscillating the piezoelectric vibrating elements, namely the oscillation transistor or the dividing capacitor or the like, is used commonly therefor, and the isolation between the piezoelectric vibrating elements is not ensured in Japanese Unexamined Patent Publication No. 2002-359521, a problem arises that the frequency control characteristics cannot accurately be adjusted for each of the piezoelectric vibrating elements.

### SUMMARY

In view of the above problems, the present invention has an advantage of providing a frequency selective oscillator capable of realizing isolation between the vibrating elements to be selected, and thus preventing various effects caused between the mutual circuits.

Further, a frequency selective oscillator can advantageously be provided in which the frequency control characteristics of piezoelectric elements can be individually adjusted to be equal to each other.

Further, an electronic instrument equipped with the frequency selective oscillator described above can advantageously be provided.

In addition, the invention has an advantage of providing a method of adjusting the frequency control characteristics capable of making the frequency control characteristics of piezoelectric elements equal by individually adjusting the frequency control characteristics of piezoelectric elements.

Frequency Selective Oscillator

In view of the above problems, a frequency selective oscillator according to one aspect of the invention, firstly, is configured to include a number of piezoelectric elements, switching sections, and a positive feedback oscillation loop circuit. The piezoelectric elements have oscillation frequencies that are different from each other. The switching sections are provided to the piezoelectric elements at both a signal input side and a signal output side of each piezoelectric element, and synchronously select either one of the piezoelectric elements. Further, the positive feedback oscillation loop circuit oscillates one of the piezoelectric elements selected with the switching sections.

More specifically, the configuration preferably includes a number of piezoelectric elements having oscillation frequencies that are different from each other, a voltage controlled phase shift circuit, switching sections, a frequency selecting section, an oscillation differential amplifier, and a feedback buffer differential amplifier. In this case, the voltage controlled phase shift circuit adjusts the phase of an input signal in accordance with a control voltage from the outside and then outputs the input signal. The switching sections are provided to the piezoelectric elements at both a signal input side and a signal output side of each piezoelectric element, and synchronously selects either one of the piezoelectric elements in accordance with a control signal from the outside. The frequency selecting section selects an output signal with a predetermined resonance frequency sent from the piezoelectric element selected with the switching sections. The oscillation differential amplifier amplifies and then outputs the resonance signal with the predetermined resonance frequency. Further, the feedback buffer differential amplifier inputs the resonance signal output from the oscillation differential amplifier. In this case, the voltage controlled phase shift circuit, the piezoelectric element selected with the switching sections, the frequency selecting section, the oscillation differential amplifier, and the feedback buffer differential amplifier form a positive feedback oscillation loop.

According to the frequency selective oscillator thus configured, the resonance frequency can be switched only by operating the switching sections, thus the required resonance frequency can be obtained with a single kind of frequency selective oscillator. Further, since the switching sections are disposed at both a signal input side and a signal output side of each piezoelectric element, and both switching sections are configured to be synchronously operated, the resonance circuit including the piezoelectric element in use is isolated from the other piezoelectric elements not selected. Therefore, the isolation from the other piezoelectric elements can be realized, thus no effects will be applied to the frequency characteristic of the selected piezoelectric elements. Further, by providing the positive feedback oscillation loop circuit including the piezoelectric element, accuracy of the oscillation frequency can be enhanced.

Further, by providing the frequency selecting section corresponding to the selected piezoelectric element, noises caused by impedance mismatch in the circuit or unnecessary noises based on abnormal vibrations can be removed, thus no jitters caused by such noises will be generated.

In the frequency selective oscillator configured as above, the frequency selecting section can include LC parallel resonance circuit and impedance elements each connected in series with the respective one of the piezoelectric vibrating elements between the piezoelectric vibrating elements and the ground. In this case, if either one of the piezoelectric elements is selected, the passive element (impedance element) connected in series with the selected piezoelectric element is connected in parallel with the LC parallel resonance circuit.

According to the configuration described above, it is not necessary to switch the passive elements (capacitors) by the LC parallel resonance circuit corresponding to the selected piezoelectric element as a unit. Therefore, a number of components corresponding to inductors to be paired with the capacitors can be omitted compared to the case in which the capacitors are switched by the LC parallel resonance circuit as a unit, thus realizing miniaturization of the frequency selective oscillator.

In the frequency selective oscillator of the above configuration, the feedback buffer differential amplifier can be a differential amplifier using a line receiver. According to such a configuration, the differential circuit can be formed as an integrated circuit, thus realizing miniaturization of the frequency selective oscillator. The line receiver is preferably an ECL line receiver in a specific form. Thus, the differential amplifier circuit can be operated at high-speed.

Further, if the frequency selection section includes a thermistor, control voltage-oscillation frequency characteristics of the frequency selective oscillator can be widely improved. Therefore, the variation in oscillation frequency caused by temperature can be reduced. In an aspect of the invention, use of an NTC thermistor is especially recommended. Thus, the high-temperature region of the characteristics is improved, and a frequency selective oscillator with stable frequency even in high-temperature environment can be provided. Note that, if the PTC thermistor is used, the characteristics are improved especially in low-temperature region.

Further, in the frequency selective oscillator of the above configuration, the feedback buffer differential amplifier can include an inverted output terminal, a noninverted output terminal. And, a signal selecting section for selecting either one of the output terminals is further implemented to form the positive feedback oscillation loop. By adopting such a configuration, since either one of the two signals output from the feedback buffer differential amplifier having phases different from each other can be selected, the amount of adjustable phase shift in the voltage controlled phase shift circuit can be set as a smaller value. Therefore, it is not necessary to provide a number of voltage controlled phase shift circuits each corresponding to a particular band frequency. Thus, miniaturization and cost reduction of the frequency selective oscillator can be realized.

Further, the frequency selective oscillator according to another aspect of the invention can be configured to include a number of piezoelectric elements having oscillation frequencies that are different from each other, switching sections, positive feedback oscillation loop circuit, and impedance elements. The switching sections are provided to the piezoelectric elements at both a signal input side and a signal output side of each of the piezoelectric elements, and synchronously select either one of the piezoelectric elements. Further, the positive feedback oscillation loop circuit oscillates one of the piezoelectric elements selected with the switching sections. Further, each of the impedance elements is provided to a respective one of the piezoelectric elements, and adjusts a frequency variation of the respective one of the piezoelectric elements with respect to a control voltage.

As a specific configuration thereof, in still another aspect of the invention, the configuration can include a number of piezoelectric elements having oscillation frequencies that are different from each other, switching sections, impedance elements, a tank circuit, and an oscillation circuit. The piezoelectric element selected with the switching sections, the impedance element provided to the selected piezoelectric element, the tank circuit, and the oscillation circuit form a positive feedback oscillation loop circuit. In this case, the switching sections are provided to the piezoelectric elements at both a signal input side and a signal output side of each of the piezoelectric elements, and synchronously select either one of the piezoelectric elements. Further, each of the impedance elements is provided to a respective one of the piezoelectric elements, and adjusts a frequency variation of the respective one of the piezoelectric elements with respect to a control voltage. Further, the tank circuit resonates in accordance with the oscillation frequency of the one of the piezoelectric elements selected with the switching sections. And, the oscillation circuit oscillates the piezoelectric element selected with the switching sections.

According to the configuration described above, the frequency variation (frequency control characteristic) of the piezoelectric element with respect to the control voltage can be adjusted by shifting up and down by adjusting the impedance element. Therefore, the characteristics of the piezoelectric elements can be made equal by individually adjusting the impedance elements each provided to the respective piezoelectric element. It is not necessary to adjust the frequency control characteristics, which differ among the piezoelectric elements, in the following circuit to the frequency selective oscillator, thus the following circuit can be simplified.

Further, each of the piezoelectric elements and the corresponding impedance element can be connected in series to form a number of serial connection circuits. The serial connection circuits can be connected in parallel forming an input connection and an output connection. And the switching sections can be connected adjacent to both the input connection and the output connection. Thus, a number of signals with different oscillation frequencies can be output. Further, since the piezoelectric element selected with the switching sections is not connected to the piezoelectric element not selected, isolation between the piezoelectric elements can be established, thus preventing the frequency characteristics of the piezoelectric elements from affecting each other.

Further, a second impedance element can be disposed in a preceding stage to the switching sections at the signal input side of the piezoelectric elements. By combining the second impedance element with the first impedance elements each provided to the respective piezoelectric element, the frequency control characteristics can be precisely adjusted in a wide range.

Further, each of the first impedance elements can be an inductor or a capacitor. Thus, the frequency characteristics of the piezoelectric elements can be shifted up and down, namely the frequency variation can be adjusted, thus the characteristics of the piezoelectric elements can be made equal.

Still further, capacitors each provided to a respective one of the piezoelectric elements for adjusting a variation of the frequency variation of the respective one of the piezoelectric elements with respect to the control voltage. Accordingly, the variation (control sensitivity) of the frequency variation of the piezoelectric element can be adjusted, thus making the characteristics of the piezoelectric elements equal.

Still further, a capacitor is disposed in a following stage of the switching sections at the signal output side of the piezoelectric elements, and adjusts variations of the frequency variations of the piezoelectric elements with respect to the control voltage. By combining this capacitor with the capacitors each provided to the respective piezoelectric element to vary the capacitance, the frequency control characteristics can be precisely adjusted in a wide range.

Further, each of the piezoelectric elements can be a surface acoustic wave resonator. Thus, a signal with a low jitter characteristic can be obtained.

Further, the frequency selective oscillator according to still another aspect of the invention can be configured to include a number of piezoelectric elements having oscillation frequencies that are different from each other, switching sections, a positive feedback oscillation loop circuit, and capacitors (C1). In this case, the switching sections are provided to the piezoelectric elements at both an input side and an output side of each of the piezoelectric elements, and synchronously select either one of the piezoelectric elements. The positive feedback oscillation loop circuit oscillates one of the piezoelectric elements selected with the switching sections. Each of the capacitors (C1) is provided to a respective one of the piezoelectric elements, and adjusts a variation of the frequency variation of the respective one of the piezoelectric elements with respect to the control voltage. Note that the positive feedback loop circuit can be configured to include the oscillation amplifier, the feedback buffer differential amplifier, the voltage controlled phase shift circuit, and the output amplifier. In this case, the oscillation amplifier inputs and then amplifies a signal output from the tank circuit. The feedback buffer differential amplifier is equipped with a buffer function for inputting the output signal of the oscillation amplifier. Further, the voltage controlled phase shift circuit shifts by a predetermined amount the phase of the output signal of the feedback buffer differential amplifier in accordance with a control voltage from the outside, and then outputs the signal to the piezoelectric elements. Further, the output amplifier is disposed outside the positive feedback oscillation loop, and inputs the output signal of the oscillation amplifier and then outputs it to the outside. By adjusting the capacitance of the capacitors, the variations (control sensitivities) of the frequency variations of the piezoelectric elements can be adjusted. Therefore, the frequency control characteristics of the piezoelectric elements implemented to the frequency selective oscillator can be made equal by adjusting the control sensitivities for every piezoelectric element. Still further, it is not necessary to adjust the frequency control characteristics, which differ among the piezoelectric elements, in the following circuit to the frequency selective oscillator, thus the following circuit can be simplified.

Further, the positive feedback oscillation loop can include a tank circuit. A capacitor for adjusting a variation of the frequency variation is disposed between the switching sections at the output side of the piezoelectric elements and the tank circuit. And the capacitor is connected in parallel with the tank circuit. By combining this capacitor with the capacitors each provided to the respective piezoelectric element to vary the capacitance, the frequency control characteristics can be precisely adjusted in a wide range.

Further, each of the piezoelectric elements can be a surface acoustic wave resonator. Thus, a signal with a low jitter characteristic can be obtained.

Electronic Instrument

An electronic instrument according to still another aspect of the invention, firstly, includes a frequency selective oscillator. The frequency selective oscillator is composed of a number of piezoelectric elements having oscillation frequencies that are different from each other, switching sections, and a positive feedback oscillation loop circuit. In this case, the switching sections are provided to the piezoelectric elements at both a signal input side and a signal output side of each piezoelectric element, and synchronously select either one of the piezoelectric elements. Further, the positive feedback oscillation loop circuit obtains a desired resonance frequency from the piezoelectric element selected with the switching sections.

In another aspect, the electronic instrument includes a frequency selective oscillator. The frequency selective oscillator includes a number of piezoelectric elements having oscillation frequencies that are different from each other, switching sections, a positive feedback oscillation loop circuit, and impedance elements. In this case, the switching sections are provided to the piezoelectric elements at both a signal input side and a signal output side of each piezoelectric element, and synchronously select either one of the piezoelectric elements. Further, the positive feedback oscillation loop circuit oscillates one of the piezoelectric elements selected with the switching sections. Each of the impedance elements is provided to a respective one of the piezoelectric elements, and adjusts a frequency variation of the respective one of the piezoelectric elements with respect to a control voltage. Thus, the electronic instrument can obtain a number of signals with different frequencies. And, since it is not necessary to adjust the frequency control characteristics, which differ among the piezoelectric elements, the configuration of the electronic instrument can be simplified.

In still another aspect, the electronic instrument includes a frequency selective oscillator. The frequency selective oscillator includes a number of piezoelectric elements having oscillation frequencies that are different from each other, switching sections, a positive feedback oscillation loop circuit, and capacitors (C1). In this case, the switching sections are provided to the piezoelectric elements at both an input side and an output side of each of the piezoelectric elements, and synchronously select either one of the piezoelectric elements. The positive feedback oscillation loop circuit oscillates one of the piezoelectric elements selected with the switching sections. Further, each of the capacitors (C1) is provided to a respective one of the piezoelectric elements, and adjusts a variation of the frequency variation of the respective one of the piezoelectric elements with respect to the control voltage. Thus, the electronic instrument can obtain a number of signals with different frequencies.

Method of Adjusting Frequency Control Characteristics

In order to obtain the advantage described above, a method of adjusting the frequency control characteristics according to still another aspect of the invention includes the following steps. A first step is comparing a frequency variation of one of piezoelectric elements implemented in a frequency selective oscillator with respect to a control voltage applied to the piezoelectric elements with a frequency variation of another of the piezoelectric elements. A second step is varying the capacitance of a plurality of capacitors each connected to a respective one of the plurality of piezoelectric elements in accordance with frequency variations with respect to the control voltage so that the frequency variations among the plurality of piezoelectric elements are adjusted within an allowable range of a reference frequency variation. According to these steps, since the variation of the frequency variation (frequency control characteristic) of each piezoelectric element with respect to the control voltage can be adjusted, the difference between the frequency variations can be adjusted within the allowable range by adjusting the frequency control characteristics of the piezoelectric elements implemented in the frequency selective oscillator.

### BRIEF DESCRIPTION OF THE DRAWINGS

Embodiments of the present invention are hereinafter described with reference to the accompanying drawings, wherein like numbers refer to like elements, and wherein:

FIG. 1 is a block diagram showing a first embodiment of a frequency selective oscillator according to the invention.

FIG. 2 is a circuit diagram showing a circuit configuration of an ECL line receiver.

FIG. 3 is a circuit diagram showing a configuration of a voltage controlled phase-shift circuit in the first embodiment of the invention.

FIG. 4 is a schematic diagram explaining frequency characteristics of a LC parallel resonance circuit in the first embodiment of the invention.

FIG. 5 is a schematic diagram regarding frequency control characteristics for explaining effects caused between a plurality of SAW resonators.

FIG. 6 is a block diagram showing a second embodiment of a frequency selective oscillator according to the invention.

FIG. 7 is a block diagram showing a third embodiment of a frequency selective oscillator according to the invention.

FIG. 8 is a block diagram showing a fourth embodiment of a frequency selective oscillator according to the invention.

FIG. 9A is a schematic diagram showing vertical variation of the frequency characteristics in accordance with adjustment of inductors in the oscillator according to the fourth embodiment.

FIG. 9B is a schematic diagram for explaining that the frequency variations of plural piezoelectric elements are adjusted to be equal to each other by adjusting inductors in the oscillator according to the fourth embodiment.

FIG. 10A is a schematic diagram showing vertical variation of the frequency characteristics in accordance with adjustment of capacitance of the oscillator according to the fourth embodiment.

FIG. 10B is a schematic diagram for explaining that the frequency characteristics of plural piezoelectric elements are adjusted to be equal to each other by adjusting capacitance of the oscillator according to the fourth embodiment.

FIG. 11 is a block diagram showing a fifth embodiment of a frequency selective oscillator according to the invention.

FIG. 12A is a schematic diagram showing vertical variation of the frequency characteristics in accordance with adjustment of capacitance of the oscillator according to the fifth embodiment.

FIG. 12B is a schematic diagram for explaining that the frequency characteristics of plural piezoelectric elements are adjusted to be equal to each other by adjusting capacitance of the oscillator according to the fifth embodiment.

FIG. 13 is a block diagram for explaining a schematic configuration of an optical interface module.

### DESCRIPTION OF THE EMBODIMENTS

The embodiments described below are some of various embodiments of the frequency selective oscillator according to an aspect of the invention. Therefore, the invention is not limited to these embodiments.

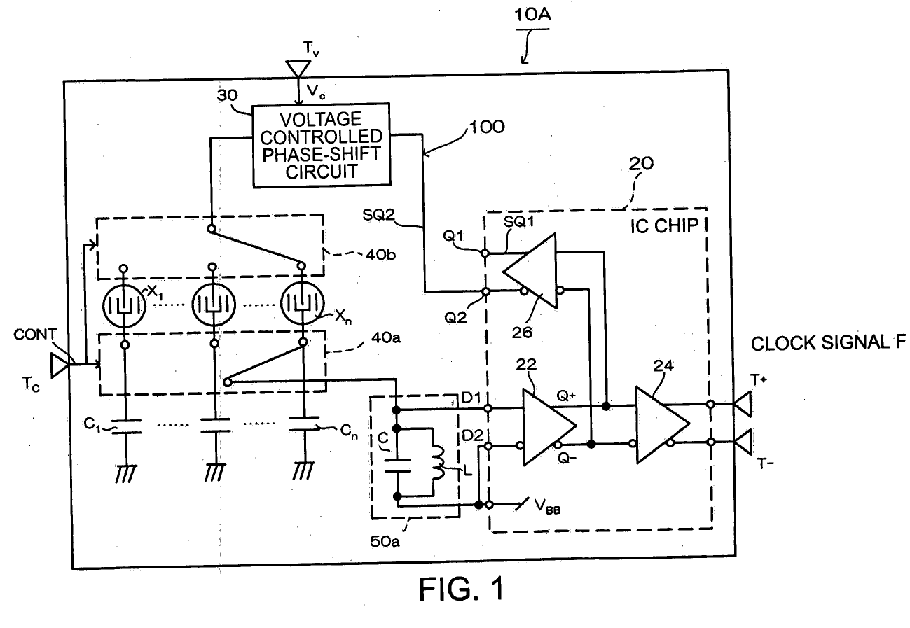

FIG. 1 is a block diagram showing a first embodiment of the frequency selective oscillator according to an aspect of the invention.

The frequency selective oscillator 10A is composed of an IC chip 20, a voltage controlled phase-shift circuit 30, a plurality of piezoelectric vibrating elements (SAW resonators, especially in the present embodiment) X1 through Xn each having a predetermined resonance frequency, switching sections 40, and a frequency selection section (an LC parallel resonance circuit) 50a. The IC chip 20 contains an oscillation differential voltage amplifier 22, an output differential voltage amplifier 24, and feedback buffer differential amplifier 26. The voltage controlled phase-shift circuit 30 adjusts the phase of an input signal by shifting the phase by a predetermined amount in accordance with a control voltage Vc supplied from the outside. The switching sections 40 perform on/off operations in accordance with a control signal from the outside.

In the frequency selective oscillator 10A configured as the above, a clock signal F is output from the IC chip 20. Further, an inverted input terminal D2 of the oscillation differential voltage amplifier 22 implemented in the IC chip 20 is supplied with a reference bias voltage VBB from the outside and the resonance frequency of the SAW resonator selected by the LC parallel resonance circuit 50a. Further, in the frequency selective oscillator 10A of the present embodiment, there is formed a positive feedback oscillation loop circuit 100 composed of the oscillation differential voltage amplifier 22, the feedback buffer differential amplifier 26, the voltage controlled phase shift circuit 30, either one of the plurality of the SAW resonators Xm (m=1 through n), and the LC parallel resonance circuit 50a. Note that the selected SAW resonator is hereinafter referred to as SAW resonator Xm.

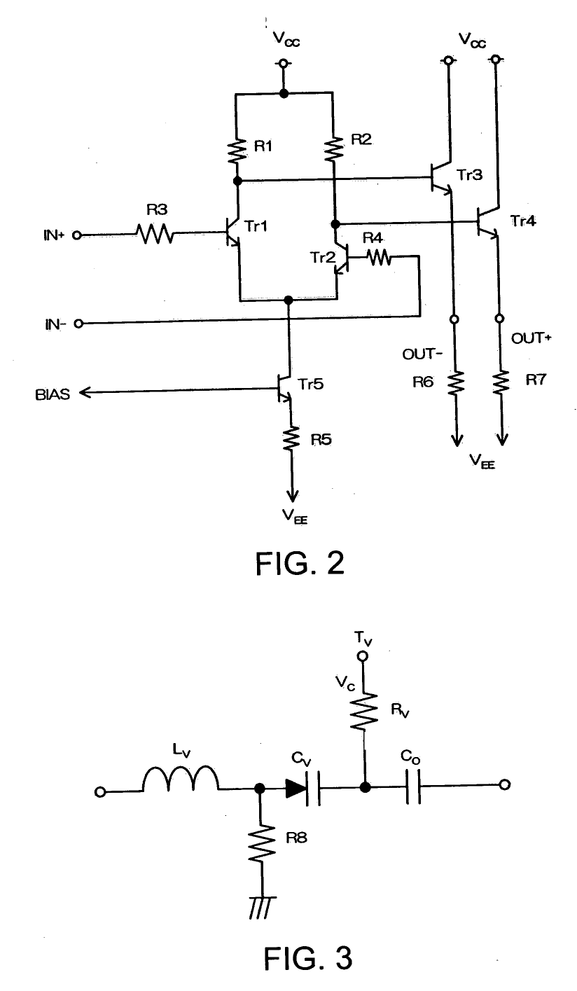

The three differential amplifiers 22, 24, and 26 are differential amplifier circuits each using the ECL (Emitter Coupled Logic) line receiver shown in FIG. 2. By using the ECL line receivers for high-frequency oscillators, high-speed operations can be realized. Further, the differential amplifiers 22, 24, and 26 for amplifying the resonance signal from the SAW resonator Xm composed of the differential amplifier circuits using the ECL line receivers, as shown in FIG. 2, can be formed as an integrated circuit, thus miniaturization of the frequency selective oscillator 10A can be realized.

In the oscillation differential voltage amplifier 22, a signal with a predetermined resonance frequency fm from the SAW resonator Xm is input to a noninverted input terminal D1 of the oscillation differential voltage amplifier 22. And then, output signals having a mutual phase difference of 180 degrees are output from a noninverted output terminal Q+ and an inverted output terminal Q−, respectively.

The output differential voltage amplifier 24 shapes the waveform of the output signals from the oscillation differential amplifier 22 to output them as clock signals F of a predetermined oscillation frequency such as, for example, 622.08 MHz.

The feedback buffer differential amplifier 26 is a differential amplifier having a buffer function whose output is output to output terminals Q1, Q2. And, each of the output terminals Q1, Q2 of the feedback buffer differential amplifier 26 using the ECL line receiver is provided with an emitter terminating resistance not shown connected thereto. Note that, FIG. 2 shows the circuit diagram with the emitter termination resisters R6, R7 connected to the output terminals OUT−, OUT+, respectively.

FIG. 3 is a circuit diagram showing a configuration of the voltage controlled phase shift circuit 30. The voltage controlled phase shift circuit 30 is composed of a voltage controlled reactance control circuit using a variable capacitance diode Cv, and leads or delays the phase of either one of the output signals SQ1 and SQ2 from the feedback buffer differential amplifier 26 by a predetermined amount to adjust it to a predetermined amount of phase in accordance with the control voltage Vc input via the voltage control terminal Tv, thus satisfying the phase requirement for the frequency selective oscillator 10A.

The LC parallel resonance circuit 50a is connected between the inverted and the noninverted input terminals D1, D2 of the oscillation differential voltage amplifier 22 as a parallel circuit of an inductor L and a capacitor C. And, it selects and outputs the resonance frequency fm of the selected SAW resonator Xm.

The switching sections 40 are provided to both the input side and the output side of the plurality of the SAW resonators X1 through Xn. Further, the switching sections 40 (40a, 40b) provided as pairs, as described above, are arranged to operate in sync with each other by a control signal CONT input from the outside via the input terminal Tc, thus selecting either one of the plurality of SAW resonators X1 through Xn. Accordingly, the oscillation circuit composed of the selected SAW resonator Xm forms a circuit completely isolated from the other SAW resonators not selected. Therefore, effects (interferences) of stubs or the like caused by sharing a part of the circuit with another resonator can be prevented. Further, by selecting either one of the SAW resonators by the switching sections 40, either one of predetermined resonance frequencies such as, for example, presently used 622.08 NHz, 644.53125 MHz, 666.51429 MHz, and 669.32658 MHz can surely be obtained.

A specific example of the frequency selective oscillator 10A of the first embodiment composed of such elements as described above will now be described with reference to FIG. 1.

In FIG. 1, the switching sections 40 (40a, 40b) are connected to the plurality of SAW resonators X1 through Xn. Note that the switching sections 40 can be composed of switches, operating in accordance with a control signal from the outside, and so on. The signal output side of the plurality of SAW resonators X1 through Xn is connected to the LC parallel resonance circuit 50a via one side (output side) of the switching sections 40.

Further, the output side terminal of each of the plurality of SAW resonators X1 through Xn is arranged to be connected to one end of the respective capacitors C1 through Cn (impedance elements) via the switching sections 40. Further, the other end of each of capacitors C1 through Cn is grounded. The present configuration is for connecting the capacitor Cm (m=1 through n) to the LC parallel resonance circuit 50a in parallel simultaneously when the respective SAW resonator Xm is selected from the SAW resonators X1 through Xn. Note that the capacitor Cm hereinafter denotes the selected capacitor.

In the above specific example, the function of either one of the capacitors C1 through Cn respectively connected to the plurality of SAW resonators can be shared with the capacitor C of the LC parallel resonance circuit 50a. According to such a configuration, one capacitor can be removed from the structure of the frequency selective oscillator 10A of the above specific example.

Further, the SAW resonator Xm and the capacitor Cm in the specific example are not limited to be directly connected, but can be configured to selectively be connected by a switching section not shown.

As described above, in the specific example, the SAW resonator Xm and the capacitor Cm are switched as a structure of serial connection. According to the present configuration, a corresponding number of components to the number of inductors to make pairs with the capacitors Cm can be reduced compared to a configuration in which the capacitance elements to be connected to the SAW resonator Xm are switched by a unit of the LC parallel resonance circuit.

Note that, as the switching sections 40 in the present embodiment, various switching sections such as mechanical switches, diode switches, switching transistors, or multiplexers can be used.

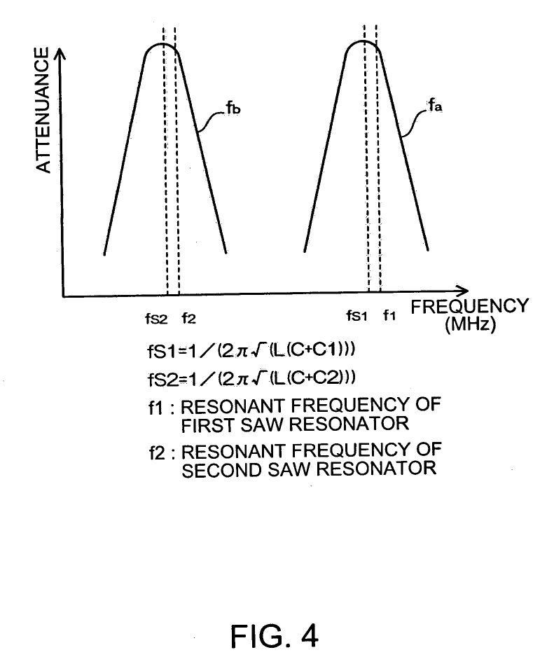

Hereinafter, the function and the frequency characteristics of the LC parallel resonance circuit 50a to which the selected capacitor Cm is connected are described with reference to FIG. 4. Note that, for the sake of simplicity of the explanation, the case in which only two SAW resonators are used in the frequency selective oscillator having a configuration as shown in FIG. 1 will be described here.

The resonance frequencies of the SAW resonators are assumed to be f1, f2, respectively. Further, when the SAW resonator X1 is selected, the resonance frequency fs1 of the LC parallel resonance circuit 50a becomes as follows, because the capacitor C1 is added (connected) thereto.
fs1=1/(2π√(L(C+C1)))
When the SAW resonator X2 is selected, the resonance frequency fs2 of the LC parallel resonance circuit 50a is expressed as follows, because the capacitor C2 is added thereto.
fs2=1/(2π√(L(C+C2)))

In FIG. 4, for example, the frequency characteristics of the LC parallel resonance circuit 50a with respect to the SAW resonator X1 is expressed as fa in view of addition of the capacitor C1, and the resonance frequency f1 of the SAW resonator X1 is a frequency selectable within the characteristics fa. Similarly, since the capacitor C2 is added thereto in response to selection of the SAW resonator X2, the frequency characteristics of the LC parallel resonance circuit 50a is shifted to the area with lower frequency (in case of C2>C1), and the resonance frequency f2 of the SAW resonator X2 becomes a frequency selectable within the characteristics fb.

As described above, by the capacitor Cm added thereto, the frequency characteristics of the LC parallel resonance circuit 50a are changed to the characteristics with which the resonance frequency fm of the corresponding SAW resonator Xm can be selected.

Incidentally, the LC parallel resonance circuit is provided for cutting off an unnecessary frequency band. Namely, the high-frequency type of frequency selective oscillator 10A using a SAW resonator resonating at several tens of MHz forms a feedback circuit composed of, in addition to SAW resonators X1 through Xn, the voltage controlled phase shift circuit 30, the LC parallel resonance circuit 50a, the differential voltage amplifiers 22, 24. Since the matching of impedance in the feedback circuit is not sufficient, an unnecessary harmonic wave component such as distortion in the high-frequency oscillation signal waveform appears.

In the frequency selective oscillator 10A shown in FIG. 1, there are feedback circuits corresponding to a plurality of paths. Therefore, abnormal oscillation caused by a mutual effect of the feedback circuits may occur. Accordingly, it becomes necessary to provide the frequency selective oscillator itself with ability to select frequencies in order to remove such unnecessary frequencies. Namely, the LC parallel resonance circuit 50a is provided with this function, thus the resonance frequency fm of the SAW resonator Xm is selected as described with reference to FIG. 4 to remove noises such as unnecessary harmonic wave components or the abnormal oscillation described above.

According to the first embodiment described above, the plurality of SAW resonators and switching sections for selecting one of the SAW resonators are provided for selecting either one of the plural SAW resonators in accordance with the control signal input from the outside via the input terminal. By the selecting operation described above, a predetermined resonance frequency corresponding to the use of the system can be obtained, thus complying with every use of individual system in, for example, an optical fiber communication system with a single kind of frequency selective oscillator.

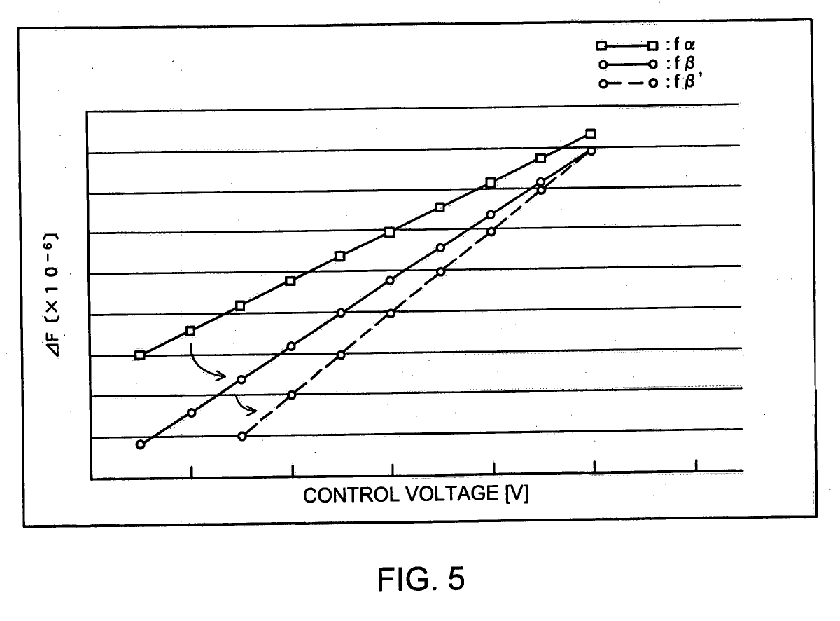

Further, by providing the switching sections to both the signal input side and the signal output side of each of the SAW resonators, effects from other piezoelectric vibrating elements having different frequency characteristics, which cannot be prevented by methods of selecting a piezoelectric vibrating element with a related switching section, can be prevented. For example, in related art, as shown in FIG. 5, if two kinds of SAW resonators respectively having the frequency characteristics denoted by the solid lines fα and fβ, an operation of adjusting the control characteristics fα to fβ effects the control characteristics fβ to be changed to fβ′ illustrated with the dotted line. Therefore, if the adjustment operation is executed on a plurality of SAW resonators taking the mutual effects into consideration, the adjustment operation becomes complicated. On the contrary, in the frequency selective oscillator equipped with the switching sections as in the embodiment of the invention, isolation between the two parts can be provided, thus preventing the mutual effects therebetween. Therefore, the frequency characteristics of each of the piezoelectric vibrating elements can be independently adjusted.

Further, since various frequencies can be selected in a single kind of frequency selective oscillator, it is sufficient to design and manufacture only this single kind of frequency selective oscillator, thus making the stock control easier.

Further, since the SAW resonators do not have any secondary vibrations as in the AT cut crystal vibrating elements, no linkage with the main vibrations nor unnecessary spurious exists. Furthermore, since no multiplier circuit for obtaining higher frequencies is required, no harmonic wave component is generated. Therefore, an advantage of generating no jitter derived therefrom can be obtained.

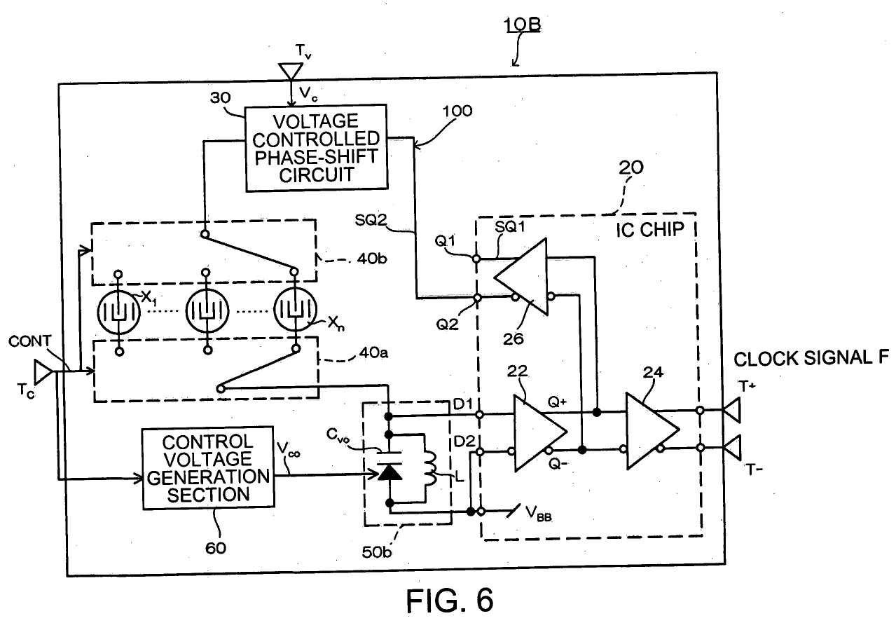

Hereinafter, a second embodiment of the frequency selective oscillator according to an aspect of the invention is described with reference to FIG. 6. The frequency selective oscillator 10B according to the present embodiment differs from the first embodiment in the following points. The capacitors C1 through Cn connected to the SAW resonators X1 through Xn are removed, and a variable capacitance diode (variable capacitance element) Cvo is used in a LC parallel resonance circuit 50b instead. And, a control voltage generating section 60 is newly provided. Since other configuration elements than mentioned above are the same as in the first embodiment, the same reference numerals are used in the drawings, and the descriptions therefor will be omitted.

In FIG. 6, the LC parallel resonance circuit 50b is composed of the variable capacitance diode Cvo and the inductor L. The capacitance of the variable capacitance diode in the LC parallel resonance circuit 50b is set in accordance with a control voltage Vco input thereto described later. The variable capacitance diode in the LC parallel resonance circuit 50b selects a signal having the resonance frequency fm of the selected SAW resonator Xm.

Further, the control voltage generating section 60 generates the control voltage Vco to be supplied to the variable capacitance diode Cvo of the LC parallel resonance circuit 50b in accordance with a control signal CONT input via an external terminal Tc.

According to the above configuration, a plurality of capacitors C1 through Cn connected to the SAW resonators X1 through Xn in the first embodiment can be removed. Thus, miniaturization of the frequency selective oscillator can be realized.

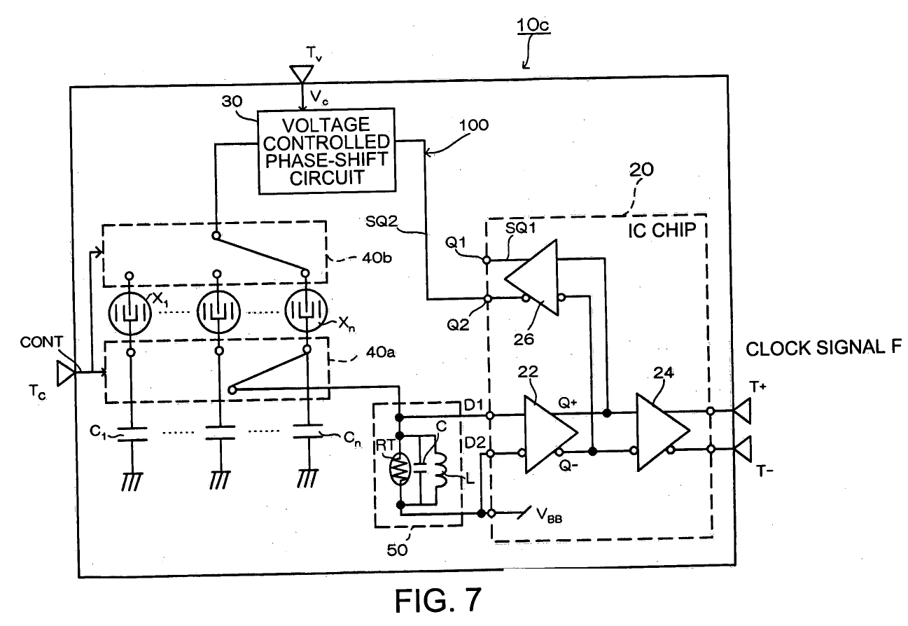

Hereinafter, a third embodiment of the frequency selective oscillator according to an aspect of the invention is described with reference to FIG. 7. The frequency selective oscillator 10C according to the present embodiment differs from the first and the second embodiments in that a NTC thermistor RT is connected in parallel to a LC parallel resonance circuit 50c. Since other parts of the configuration than described above are the same as the above embodiments, the same reference numerals are used in the drawings and descriptions therefor will be omitted.

By providing the NTC thermistor RT to the LC parallel resonance circuit 50c, the frequency characteristics in a high-temperature region is improved. And, a frequency selective oscillator having stable frequencies even in a high environmental temperature can be realized.

In each of the embodiments described above, the voltage controlled phase shift circuit 30 can be connected to the feedback buffer differential amplifier 26 via a switching section.

Further, the differential amplifiers in each of above embodiments can be replaced with single-ended (with single input and single output) amplifiers.

Further, although the piezoelectric vibrating elements are particularly explained as the SAW resonators in the above embodiments, AT cut crystal vibrating elements or tuning fork crystal vibrating elements can also be adopted if the switching sections described above are used in the voltage controlled oscillators.

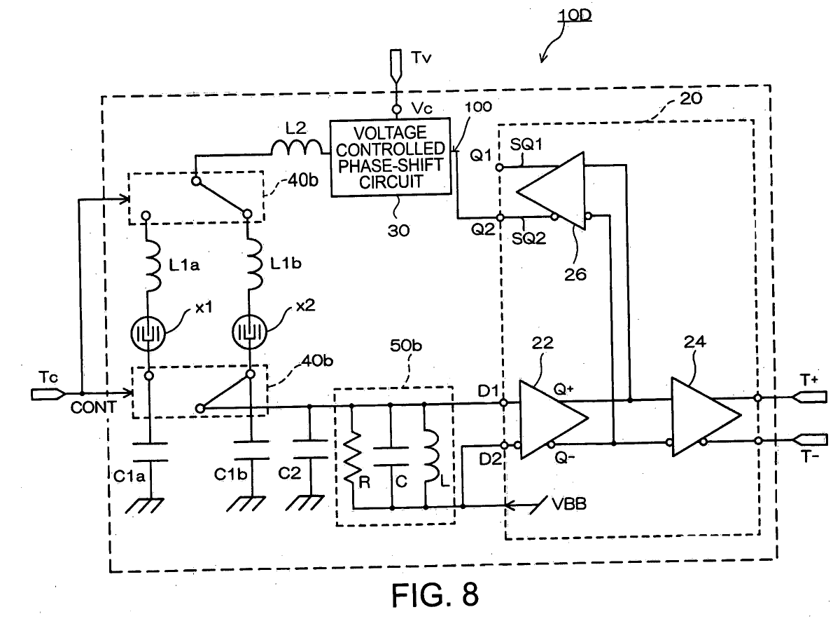

A configuration block diagram of a fourth embodiment of the frequency selective oscillator according to an aspect of the invention is shown in FIG. 8. The frequency selective oscillator according to the present embodiment has a configuration including a plurality of piezoelectric elements having different oscillation frequencies from each other, switching sections, a positive feedback oscillation loop circuit, and impedance elements. The switching sections are provided to each of the piezoelectric vibrating elements in the signal input side and the signal output side thereof and synchronously select either one of the plural piezoelectric elements. The positive feedback oscillation loop circuit oscillates the piezoelectric oscillating element selected with the switching sections. The impedance element is provided to each of the piezoelectric oscillating elements and adjusts frequency variation of the piezoelectric element with respect to the control voltage thereof.

In FIG. 8 showing a frequency selective oscillator 10D according to the fourth embodiment, a configuration is illustrated in which surface acoustic wave (SAW) resonators are used as the piezoelectric elements, and inductors L1, L2 are used as the impedance elements. The frequency selective oscillator 10D is composed of the SAW resonators X1, X2 as the piezoelectric elements, the inductors L1, L2, the capacitors C1, C2, the switching sections 40 (40a, 40b), a tank circuit 50d as a frequency selecting section, the oscillation differential voltage amplifier 22, the output differential voltage amplifier 24, the feedback buffer differential amplifier 26 and the voltage controlled phase shift circuit 30, thus forming the frequency selective oscillator. And, the positive feedback oscillation loop circuit is formed of the SAW resonators X1, X2, the inductors L1, L2, the tank circuit 50d, the oscillation differential voltage amplifier 22, the feedback buffer differential amplifier 26, and the voltage controlled phase shift circuit 30.

A plurality of SAW resonators X1, X2 is provided, which have oscillation frequencies that are different from each other. Since no other unnecessary vibrations than the main vibration present in the SAW resonators X1, X2, no jitter is advantageously caused. The inductors L1 (L1a, L1b) are connected to each of the SAW resonators X1, X2. The switching sections 40 (40a, 40b) are provided to both ends of the circuits each having either one of the SAW resonators X1, X2 and one of the inductors L1 connected serially. The circuits are then connected in parallel, and the switching sections 40 are provided to the connection areas thereof. Further, either one of the capacitors C1 (C1a, C1b) is serially connected to either one of the circuits via one group of the switching sections 40a.

Note that, although a configuration having two SAW resonators X1, X2 is illustrated in FIG. 8, the configuration does not place any limitations, and another configuration having three or more of SAW resonators with different oscillation frequencies can be adopted. Further, the switching sections 40 have a configuration of operating at the same time in accordance with the control signal CONT input via the switching terminal Tc to select either one of the plural SAW resonators X1, X2. Further, an inductor L2 is provided in the preceding stage to the switching sections 40b provided to the input side of the SAW resonators X1, X2, namely between the other group of the switching sections 40b and the voltage controlled phase shift circuit 30. The inductors L1, L2 are used for adjusting the frequency variation (frequency control characteristics) of the SAW resonators X1, X2 with respect to the control voltage.

The tank circuit 50d is composed of a resistor R, and a parallel resonance circuit of an inductor L and a capacitor C. One end of the tank circuit is connected to a node between the SAW resonators X1, X2 and the noninverted input terminal D1 of the oscillation differential voltage amplifier 22. Further, the other end of the tank circuit 50d is connected to the inverted input terminal D2 of the oscillation differential voltage amplifier 22. One end of the capacitor C2 is connected to a node between the tank circuit 50d and the one group of the switching sections 40a, and the other end of the capacitor C2 is connected to the ground. The capacitor C2 and the capacitor C1 connected to the SAW resonator X1, X2 selected with the switching sections 40 are connected in parallel to the tank circuit 50d to be used for adjusting a variation (control sensitivity) of the relationship between the frequency variation and the control voltage. Further, the tank circuit resonates at a predetermined frequency after connected in parallel to the capacitors C1, C2.

Further, the oscillation differential voltage amplifier 22, the output differential voltage amplifier 24, and the feedback buffer differential amplifier 26 are integrated to form a single integrated circuit (IC) chip 20. The IC chip 20 forms an oscillation circuit. Further, since these differential amplifiers 22, 24, 26 are composed of differential amplifier circuits implementing the ECL line receivers (emitter coupled logic), and accordingly easy to be formed as the integrated circuit, thus easily miniaturizing the frequency selective oscillator 10D.

The noninverted input terminal D1 of the oscillation differential voltage amplifier 22 is connected to the switching sections 40 to input the output signal of the SAW resonators X1, X2 to the noninverted input terminal D1. Further, the inverted input terminal D2 of the oscillation differential voltage amplifier 22 is connected to the switching sections 40 via the tank circuit 50d. Still further, the inverted input terminal D2 is applied with a reference bias voltage VBB output from the IC chip 20. Note that a configuration can be adopted, in which the output signal from the SAW resonators X1, X2 is input to the inverted input terminal D2 of the oscillation differential voltage amplifier 22, and the bias voltage VBB is input to the noninverted input terminal D1. And, the oscillation differential voltage amplifier 22 has a configuration for outputting the output signals having a mutual phase difference of 180 degrees from the noninverted output terminal Q+ and the inverted output terminal Q−, respectively.

Further, the noninverted input terminal of the output differential voltage amplifier 24 is connected to the noninverted output terminal Q+ of the oscillation differential voltage amplifier 22, while the inverted input terminal is connected to the inverted output terminal Q− of the oscillation differential voltage amplifier 22. And, the output differential voltage amplifier 24 shapes the waveform of the output signals from the oscillation differential voltage amplifier 22 to output via the output terminals T+, T− as clock signals.

Further, the feedback buffer differential amplifier 26 is a differential amplifier having a buffer function. The inverted input terminal of the feedback buffer differential amplifier 26 is connected to the inverted output terminal Q− of the oscillation differential voltage amplifier 22, while the noninverted input terminal is connected to the noninverted output terminal Q+ of the oscillation differential voltage amplifier 22. And, a signal SQ1 output from the noninverted output terminal Q1 of the feedback buffer differential amplifier 26 is output to the outside of the frequency selective oscillator 10D. Furthermore, a signal SQ2 output from the inverted output terminal Q2 is input to the voltage controlled phase shift circuit 30 as an output signal for the positive feedback oscillation loop circuit. Note that the output signal SQ1 of the noninverted output terminal Q1 can be used as the output signal for the positive feedback oscillation loop circuit, and the output signal SQ2 of the inverted output terminal Q2 can be output to the outside of the frequency selective oscillator 10D.

The voltage controlled phase shift circuit 30 has the same configuration as shown in FIG. 3 described in the first embodiment section, and is composed of a voltage controlled reactance control circuit using a variable capacitance diode Cv, and leads or delays the phase of either one of the output signals SQ1 and SQ2 from the feedback buffer differential amplifier 26 by a predetermined amount to adjust it to a predetermined amount of phase in accordance with the control voltage Vc input via the voltage control terminal Tv, thus satisfying the phase requirement for the frequency selective oscillator 10D.

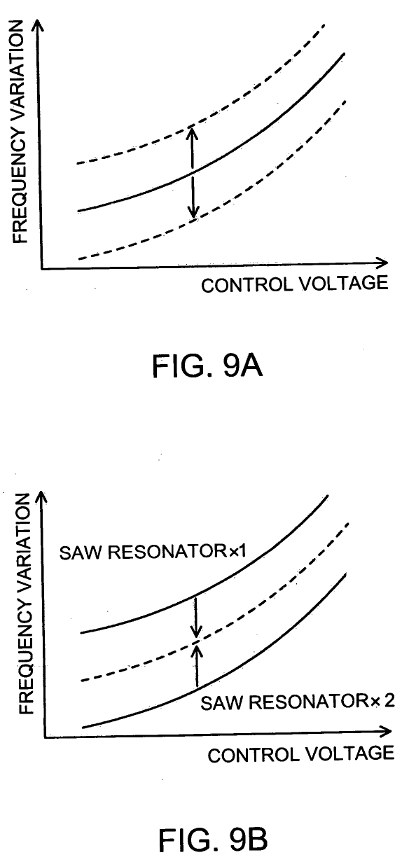

The adjustment of the frequency control characteristics using the inductors L1, L2 will now be described. FIGS. 9A and 9B show schematic diagrams for explaining the adjustment of the frequency variation in the frequency control characteristics of the SAW resonators X1, X2. FIG. 9A shows the schematic diagram for explaining a case in which the variation shifts up and down, while FIG. 9B shows the schematic diagram for explaining a case in which the characteristics of the SAW resonators X1, X2 are made equal. By varying the inductance of the inductors L1, L2, the frequency variations of the frequency control characteristics of the SAW resonators X1, X2 can be adjusted. Namely, by varying the inductance, the solid line illustrated in FIG. 9A is shifted to the dotted lines illustrated above or below the solid line, thus the frequency variation is changed. Therefore, the frequency characteristics of the SAW resonators X1, X2 different from each other as illustrated by the solid lines in FIG. 9B, without the inductors L1, L2 to be provided to the SAW resonators X1, X2, can be made equal as illustrated by the dotted line in FIG. 9B if the frequency variations in the frequency control characteristics of the SAW resonators X1, X2 are adjusted by varying the inductance of the inductors L1 provided to the SAW resonators X1, X2 together with the inductance of the inductor L2.

Note that, if the inductors L1 and L2 are used, the inductor L2 is used for adjusting the oscillation frequencies of all of the SAW resonators X1, X2, and the inductors L1 are used for adjusting the oscillation frequencies of each the SAW resonators. Therefore, by using an inductor with large inductance as the inductor L2, and by using inductors with small inductance as the inductors L1, the frequencies can be varied precisely in a wide range. Therefore, the frequency control characteristics can also be adjusted precisely in a wide range. Further, a configuration without the inductor L2 can also be adopted depending on the practical situation. Further, although the case in which the inductors L1, L2 are used as the impedance elements is described in the present embodiment, capacitors can also be used instead of the inductors.

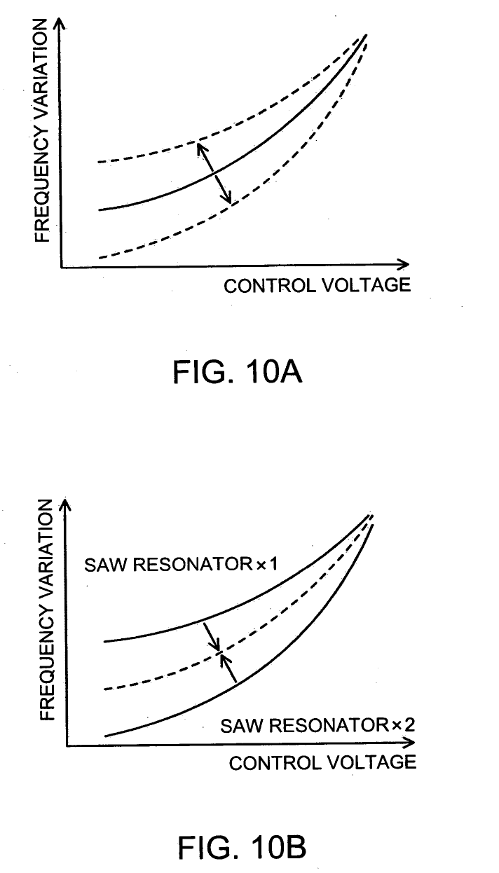

The adjustment of the frequency control characteristics using the capacitors C1, C2 will now be described. FIGS. 10A and 10B show schematic diagrams for explaining the adjustment of the control sensitivity in the frequency control characteristics of the SAW resonators X1, X2. FIG. 10A shows the schematic diagram for explaining a case in which the control sensitivity of the characteristics is varied, while FIG. 10B shows the schematic diagram for explaining a case in which the characteristics of the SAW resonators X1, X2 are made equal. By varying the capacitance of the capacitors C1, C2 connected to the SAW resonators X1, X2, the variations (control sensitivities) of the relationships between the frequency variation and the control voltage in the SAW resonators X1, X2 are varied. That is, the control sensitivity of the characteristics is varied by varying the capacitance, and the solid line illustrated in FIG. 10A is changed to the dotted lines. Therefore, the control sensitivity of the SAW resonators X1, X2 different from each other as illustrated by the solid lines in FIG. 10B, without using the capacitors C1, C2, can be made equal as illustrated by the dotted line in FIG. 10B if the control sensitivity in the frequency control characteristics of the SAW resonators X1, X2 are adjusted by varying the capacitance of the capacitors C1 connected to the SAW resonators X1, X2 together with the capacitance of the capacitor C2.

Note that, if the capacitors C1, C2 are used, by using a capacitor with large capacitance as the capacitor C2, and by using capacitors with small capacitance as the capacitor C1, the capacitance can be varied precisely in a wide range. Therefore, the control sensitivity of the frequency control characteristics can also be adjusted precisely in a wide range. Further, a configuration without the capacitor C2 can also be adopted depending on the practical situation.

Further, if both the adjustment of the frequency variation and the adjustment of control sensitivity are necessary for the frequency control characteristics of the SAW resonators X1, X2, the characteristics of the SAW resonators X1, X2 can be made equal by varying both the inductance of the inductors L1, L2 and the capacitance of the capacitors C1, C2.

An operation of the frequency selective oscillator 10D will now be described. Firstly, the switching sections 40 select either one of the SAW resonators X1, X2, namely the SAW resonator X1 or the SAW resonator X2, in accordance with the control signal CONT input via the switching terminal Tc. The selected SAW resonator X1 or X2 forms the positive feedback oscillation loop circuit together with the inductors L2, L1, the tank circuit 50d, the IC chip 20, and the voltage controlled phase shift circuit 30. The selected SAW resonator X1 or X2 inputs a signal via the inductors L1, L2, and oscillates with a frequency inherent to the selected SAW resonator X1 or X2 to output a signal. And, the signal output from the SAW resonator X1 or X2 is input to the oscillation differential voltage amplifier 22 via the tank circuit 50d. The output signals from the oscillation differential voltage amplifier 22 have a mutual phase difference of 180 degrees, and are input to the output differential voltage amplifier 24 and the feedback buffer differential amplifier 26. The output differential voltage amplifier 24 shapes the waveform of the output signals from the oscillation differential voltage amplifier 22 to output to the outside of the frequency selective oscillator 10D as clock signals via the output terminals T+, T−. Further, the output signals are output to the noninverted output terminal Q1 and the inverted output terminal Q2 via the feedback buffer differential amplifier 26. And, the voltage controlled phase shift circuit 30 adjusts the phase of the output signal SQ2 output from the inverted output terminal Q2 of the feedback buffer differential amplifier 26 to an appropriate phase in accordance with the control voltage Vc input via the voltage control terminal Tv. Further, the signal SQ1 output from the noninverted output terminal Q1 is output to the outside of the frequency selective oscillator 10D.

Since the frequency selective oscillator 10D has the SAW resonators X1, X2 each connected to the inductor L1, the frequency variations of the frequency control characteristics of the SAW resonators X1, X2 can be adjusted independently from each other. And, by adjusting the characteristics of the SAW resonators X1, X2 independently, the characteristics of all of the SAW resonators X1, X2 provided to the frequency selective oscillator 10D can be made equal. Further, since the inductor L2 is provided between the voltage controlled phase shift circuit 30 and the switching sections 40, the inductance can be varied precisely in a wide range by adjusting the inductance in combination of the inductors L1 and the inductor L2, thus precisely adjusting the characteristics. Accordingly, signals having a constant frequency variation with respect to the control voltage can be output to a circuit connected to the output side of the frequency selective oscillator 10D. Further, since it is not necessary to adjust the frequency control characteristics in accordance with the SAW resonators X1, X2, the circuit to be connected to the output side of the frequency selective oscillator 10D can be simplified.

Further, since the capacitor C1 is connected to each of the SAW resonators X1, X2, the control sensitivity of the frequency control characteristics of the SAW resonators X1, X2 can be adjusted independently from each other. Furthermore, the control sensitivity of the characteristics can be precisely adjusted by using the capacitor C2. And, by adjusting the characteristics of the SAW resonators X1, X2 independently, the control sensitivity of all of the SAW resonators X1, X2 provided to the frequency selective oscillator 10D can be made equal.

Still further, by varying the inductance of the inductors L1, L2 to adjust the frequency variation of the characteristics as well as varying the capacitance of the capacitors C1, C2 to adjust the control sensitivity of the characteristics, the characteristics of all of the SAW resonators X1, X2 provided to the frequency selective oscillator 10D can be made equal.

Further, since the switching sections 40 are provided to both the input side and the output side of the SAW resonators X1, X2 to synchronously select either one of the plural SAW resonators X1, X2 in accordance with the control signal CONT input to the switching sections 40 from the switching terminal Tc, only one of the SAW resonators X1, X2 is connected to the positive feedback oscillation loop circuit. Therefore, the isolation between one of the SAW resonators X1, X2 selected with the switching sections 40 and the other of the SAW resonators X1, X2 not selected can be ensured, thus preventing the mutual effects in the frequency control characteristics. Further, since a plurality of signals with different frequencies can be output from a single frequency selective oscillator 10D, a predetermined oscillation frequency in accordance with a specification of an electronic instrument. And, a single kind of frequency selective oscillator 10D can comply with various individual system specifications in the optical fiber communication system.

Furthermore, since the capacitors C1, C2 are connected in parallel to the tank circuit 50d, it is not necessary to switch the entire tank circuit 50d. Therefore, several inductor components can be removed, thus preventing the size of the frequency selective oscillator from growing large.

Further, although, in the present embodiment, the description is made regarding the case in which the SAW resonators X1, X2 are used as the piezoelectric elements, other types of piezoelectric vibrating elements such as AT cut type can be used as the piezoelectric elements as is the case with the first through third embodiments. Since the SAW resonators X1, X2 do not have any secondary vibrations unlike the piezoelectric vibrating elements, any linkage of the main vibration with the secondary vibration or unnecessary spurious does not exist. Furthermore, since no multiplier circuit for obtaining higher frequencies is required, no harmonic wave component is generated. Therefore, the SAW resonators X1, X2, which do not generate any jitter derived therefrom, can output high quality signals.

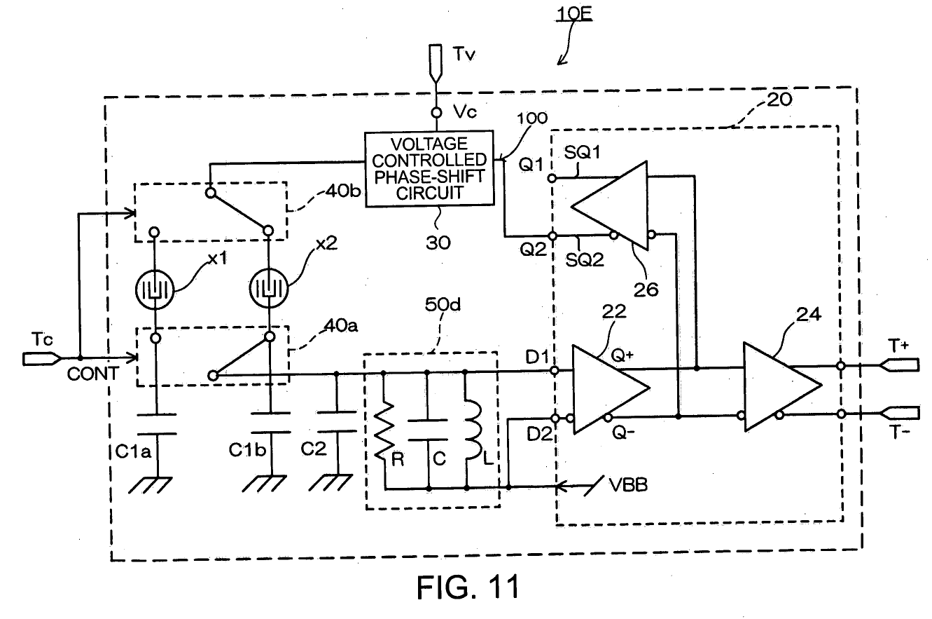

A configuration block diagram of a fifth embodiment of the frequency selective oscillator according to an aspect of the invention is shown in FIG. 11. The frequency selective oscillator according to the present embodiment has a configuration including a plurality of piezoelectric elements having different oscillation frequencies from each other, switching sections, a positive feedback oscillation loop circuit, and capacitors (C1). The switching sections are provided to each of the piezoelectric vibrating elements in the signal input side and the signal output side thereof and synchronously select either one of the plural piezoelectric elements. The positive feedback oscillation loop circuit oscillates the piezoelectric element selected with the switching sections. The capacitance is provided to each of the piezoelectric elements and adjusts frequency variation of the piezoelectric element with respect to the control voltage thereof. The frequency selective oscillator 10E according to the fifth embodiment is obtained by removing the inductors L1 and L2 as the impedance elements from the frequency selective oscillator according to the fourth embodiment, and the other sections are the same as those of the fourth embodiment. Namely, the frequency selective oscillator 10E according to the fifth embodiment is composed of the SAW resonators X1, X2, the capacitors C1, C2, the switching sections 40 (40a, 40b), a tank circuit 50d as a frequency selecting section, the oscillation differential voltage amplifier 22, the output differential voltage amplifier 24, the feedback buffer differential amplifier 26 and the voltage controlled phase shift circuit 30, thus forming the frequency selective oscillator. And, the positive feedback oscillation loop is formed of the SAW resonators X1, X2, the tank circuit 50d, the oscillation differential voltage amplifier 22, the feedback buffer differential amplifier 26, and the voltage controlled phase shift circuit 30. And, one end of each of the capacitors C1 (C1a, C1b) is connected to the respective one of the SAW resonators X1, X2, and the other end thereof is connected to the ground. One end of the capacitor C2 is connected to a node between the tank circuit 50d and the one group of the switching sections 40a, and the other end of the capacitor C2 is connected to the ground. And, the capacitor C2 and the capacitor C1 connected to the SAW resonator X1, X2 selected with the switching sections 40 are connected in parallel to the tank circuit 50d to be used for adjusting a variation (control sensitivity) of the frequency variation (frequency control characteristics) with respect to the control voltage. Further, the tank circuit resonates at a predetermined frequency after connected in parallel to the capacitors C1, C2. Since the other parts of the configuration are the same as the oscillator 10D according to the fourth embodiment, the description therefor will be omitted.

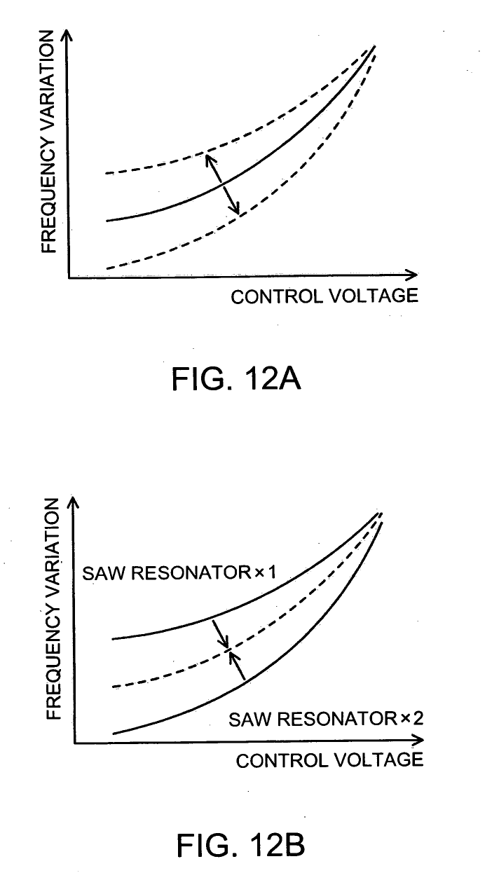

The adjustment of the frequency control characteristics using the capacitors C1, C2 will now be described. FIGS. 12A and 12B show schematic diagrams for explaining the adjustment of the control sensitivity in the frequency control characteristics of the SAW resonators X1, X2. FIG. 12A shows the schematic diagram for explaining a case in which the control sensitivity of the characteristics is varied, while FIG. 12B shows the schematic diagram for explaining a case in which the characteristics of the SAW resonators X1, X2 are made equal. By varying the capacitance of the capacitors C1, C2 connected to the SAW resonators X1, X2, the variation (control sensitivity) of the frequency control characteristics in the SAW resonators X1, X2 is varied.

Incidentally, if the capacitors C1, C2 are not connected to the SAW resonators, the relationships between the frequency variation and the control voltage in the SAW resonators become different from each other, and even run off the tolerance level of the reference frequency variation. However, by varying the capacitance of the capacitors C1, C2, the control sensitivity of the characteristics is varied, thus the solid line illustrated in FIG. 12A is changed to the dotted lines. Therefore, the control sensitivity of the SAW resonators X1, X2 different from each other as illustrated by the solid lines in FIG. 1 2B, without using the capacitors C1, C2, can be made equal as illustrated by the dotted line in FIG. 12B if the control sensitivity in the frequency control characteristics of the SAW resonators X1, X2 are adjusted by varying the capacitance of the capacitors C1 connected to the SAW resonators X1, X2 together with the capacitance of the capacitor C2. Accordingly, the relationships between the frequency variations and the control voltage of the SAW resonators are made equal to each other, and remain within the tolerance level of the reference frequency variation.

Note that, also in the present embodiment, if the capacitors C1, C2 are used, by using a capacitor with large capacitance as the capacitor C2, and by using capacitors with small capacitance as the capacitor C1, the capacitance can be varied precisely in a wide range. Therefore, the control sensitivity of the frequency control characteristics can also be adjusted precisely in a wide range. Further, a configuration without the capacitor C2 can also be adopted depending on the practical situation.

Since the frequency selective oscillator 10E has the SAW resonators X1, X2 each connected to the capacitor C1, the control sensitivities of the frequency control characteristics of the SAW resonators X1, X2 can be adjusted independently from each other. Further, since the capacitor C2 is provided, the capacitance can be varied precisely in a wide range by adjusting the capacitance of the capacitors C1 and the capacitor C2 in combination, thus the control sensitivity of the characteristics can be precisely adjusted. Therefore, by adjusting the characteristics of the SAW resonators X1, X2 independently, the control sensitivity of all of the SAW resonators X1, X2 provided to the frequency selective oscillator 10E can be made equal. And, signals having a constant frequency variation with respect to the control voltage can be output to a circuit connected to the output side of the frequency selective oscillator 10E. Further, since it is not necessary to adjust the frequency control characteristics in accordance with the SAW resonators X1, X2 in the circuit to be connected to the output side of the frequency selective oscillator 10E, the circuit can be simplified.

Furthermore, since the capacitors C1, C2 are connected in parallel to the tank circuit 50d, it is not necessary to switch the entire tank circuit 50d. Therefore, several inductor components can be removed, thus preventing the size of the frequency selective oscillator from growing large.

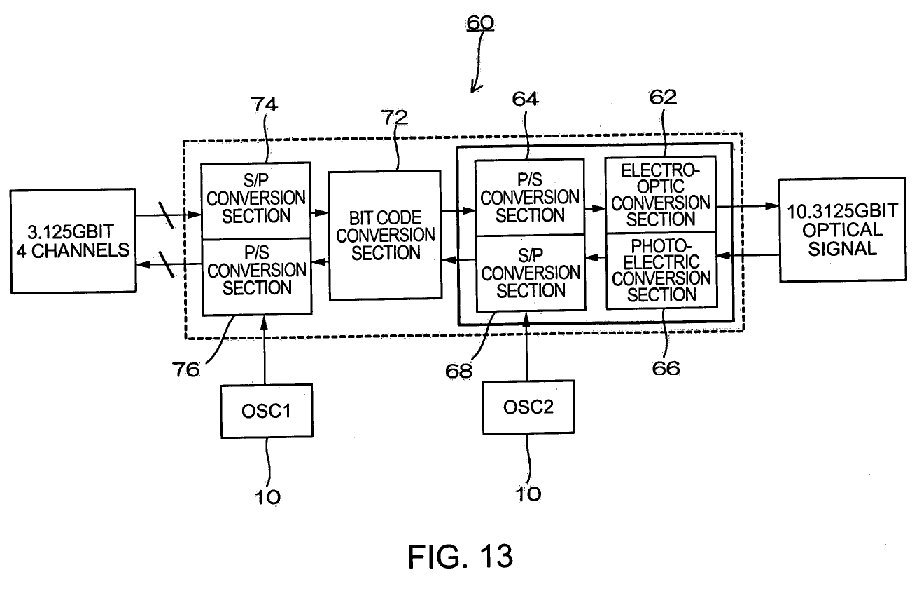

A sixth embodiment shown in FIG. 13 will now be described. In the sixth embodiment, an example of an electronic instrument implementing any one of the frequency selective oscillators 10A through 10E explained as the first through fifth embodiments. FIG. 13 shows a block diagram for explaining a schematic configuration of an optical interface module. The optical interface module 60 is for performing signal conversion between optical signals and electrical signals in order for executing data communication and so on through an optical network. For example, it performs signal conversion between an optical signal of 10.3125 Gbit/sec and an electrical signal (4 channels) of 3.125 Gbit/sec. An electro-optic conversion section 62 converts an electrical signal output from parallel to serial (P/S) conversion section 64 into an optical signal to output it to an optical network. A photo-electric conversion section 66 converts an optical signal input from the optical network into an electrical signal to output it to a serial to parallel (S/P) conversion section 68. The frequency selective oscillator 10 denotes any one of the frequency selective oscillators 10A through 10E, and is equipped with four SAW resonators X. And, clock signals output from the frequency selective oscillator 10 are used as reference signals in a S/P conversion section 74 and a P/S conversion section 76 both of 3.125 Gbit/sec, and a P/S conversion section 64 and a S/P conversion section 68 both of 10.3125 Gbit/sec. A pair of the S/P conversion section 74 and the P/S conversion section 76 is connected to a pair of the P/S conversion section 64 and the S/P conversion section 68 via a bit code conversion section 72.

As described above, since any one of the frequency selective oscillators 10A through 10E is equipped on the optical interface module 60 as the frequency selective oscillator 10, the optical interface module 60 can obtain a number of signals having different frequencies with only one of the frequency selective oscillators 10A through 10E. And, the frequency control characteristics of SAW resonators X mounted on any one of the oscillators 10A through 10E have the same relationship between the frequency variation and the control voltage, the circuit following the any one of the frequency selective oscillators 10A through 10E do not need to have a circuit for adjusting the frequency variation, thus the configuration of the optical interface module 60 can be simplified.

Further, the optical interface module 60 uses the frequency selective oscillator 10 which forms a simplified tank circuit 50 for the selected one of the SAW resonators X to drastically reduce unnecessary jitters and is, accordingly, highly stabilized. Since the timing margin between the communicated data and the clock signals is thus obtained, stable data communication via the optical network without any malfunctions can be performed. Further, even in a high-speed network system of 10 Gbit/sec capable of transmitting a large amount of data such as moving images, a stable operation can easily be realized.

Note that, since the frequency selective oscillators 10A through 10E belong to the frequency selective oscillators, they can be applied as a phase-locked circuit composed of a loop filter and a voltage controlled oscillator. Therefore, the frequency selective oscillators 10A through 10E can be implemented to electronic instruments equipped with the phase-locked circuits.

1. A frequency selective oscillator, comprising:
a plurality of piezoelectric elements having oscillation frequencies that are different from each other;
a plurality of switching sections provided at both a signal input side and a signal output side of each of the plurality of piezoelectric elements for synchronously selecting any one of the plurality of piezoelectric elements; and
a positive feedback oscillation loop circuit oscillating one of the plurality of piezoelectric elements selected with the plurality of switching sections.

2. A frequency selective oscillator, comprising:
a plurality of piezoelectric elements having oscillation frequencies that are different from each other;
a voltage controlled phase shift circuit adjusting the phase of an input signal in accordance with a control voltage from the outside and then outputting the input signal;
a plurality of switching sections provided at both a signal input side and a signal output side of each of the plurality of piezoelectric elements for synchronously selecting any one of the plurality of piezoelectric elements in accordance with a control signal from the outside;
a frequency selecting section for selecting an output signal with a predetermined resonance frequency sent from the one of the plurality of piezoelectric elements selected with the plurality of switching sections;
an oscillation differential amplifier amplifying and outputting a resonance signal with the predetermined resonance frequency; and
a feedback buffer differential amplifier inputting the resonance signal output from the oscillation differential amplifier,
wherein the voltage controlled phase shift circuit, the one of the plurality of piezoelectric elements selected with the plurality of switching sections, the frequency selecting section, the oscillation differential amplifier, and the feedback buffer differential amplifier form a positive feedback oscillation loop.

3. The frequency selective oscillator according to claim 2, wherein
the frequency selecting section comprises:
a LC parallel resonance circuit; and
a plurality of impedance elements each connected in series to a respective one of the plurality of piezoelectric elements between the signal output side of the respective one of the plurality of piezoelectric elements and ground,
the impedance elements being connected in parallel to the LC parallel resonance circuit.

4. The frequency selective oscillator according to claim 2, wherein
the feedback buffer differential amplifier comprises a differential amplifier circuit using a line receiver.

5. The frequency selective oscillator according to claim 2, wherein
the frequency selecting section includes a thermistor.

6. An electronic instrument, comprising
a frequency selective oscillator, including:
a plurality of piezoelectric elements having oscillation frequencies that are different from each other;
a plurality of switching sections provided at both a signal input side and a signal output side of each of the plurality of piezoelectric elements for synchronously selecting any one of the plurality of piezoelectric elements; and
a positive feedback oscillation loop circuit obtaining a desired resonance frequency from the one of the plurality of piezoelectric elements selected with the switching sections.

7. A frequency selective oscillator, comprising:
a plurality of piezoelectric elements having oscillation frequencies that are different from each other;
a plurality of switching sections provided at both a signal input side and a signal output side of each of the plurality of piezoelectric elements for synchronously selecting any one of the plurality of piezoelectric elements;
a positive feedback oscillation loop circuit oscillating one of the plurality of piezoelectric elements selected with the plurality of switching sections; and
a plurality of first impedance elements each provided to a respective one of the plurality of piezoelectric elements and adjusting a frequency variation of the respective one of the plurality of piezoelectric elements with respect to a control voltage.

8. A frequency selective oscillator, comprising:
a plurality of piezoelectric elements having oscillation frequencies that are different from each other;
a plurality of switching sections provided at both a signal input side and a signal output side of each of the plurality of piezoelectric elements for synchronously selecting any one of the plurality of piezoelectric elements;
a plurality of impedance elements each provided to a respective one of the plurality of piezoelectric elements and adjusting a frequency variation of the respective one of the plurality of piezoelectric elements with respect to a control voltage;
a tank circuit resonating in accordance with the oscillation frequency of the one of the plurality of piezoelectric elements selected with the plurality of switching sections; and
an oscillation circuit oscillating the one of the plurality of piezoelectric elements selected with the plurality of switching sections, wherein the one of the plurality of piezoelectric elements selected with the plurality of switching sections, one of the plurality of impedance elements provided to the one of the plurality of piezoelectric elements selected with the plurality of switching sections, the tank circuit, and the oscillation circuit form a positive feedback oscillation loop circuit.

9. The frequency selective oscillator according to claim 7, wherein
each of the plurality of piezoelectric elements and the corresponding one of the plurality of first impedance elements are connected in series to form a plurality of serial connection circuits,
the plurality of serial connection circuits is connected in parallel forming an input connection and an output connection, and
the plurality of switching sections is connected adjacent to both the input connection and the output connection.

10. The frequency selective oscillator according to claim 7, comprising
a second impedance element disposed in a preceding stage to the plurality of switching sections at the signal input side of the plurality of piezoelectric elements and adjusting the frequency variation of the respective one of the plurality of piezoelectric elements with respect to a control voltage.

11. The frequency selective oscillator according to claim 7, wherein
each of the plurality of first impedance elements comprises one of an inductor and a capacitor.

12. The frequency selective oscillator according to claim 7, comprising
a plurality of capacitors each provided to a respective one of the plurality of piezoelectric elements adjusting a variation of the frequency variation of the respective one of the plurality of piezoelectric elements with respect to the control voltage.

13. The frequency selective oscillator according to claim 12, comprising
a second capacitor disposed in a following stage of the plurality of switching sections at the signal output side of the plurality of piezoelectric elements adjusting variations of the frequency variations of the plurality of piezoelectric elements with respect to the control voltage.

14. The frequency selective oscillator according to claim 7, wherein
each of the plurality of piezoelectric elements comprises a surface acoustic wave resonator.

15. An electronic instrument, comprising
a frequency selective oscillator, including:
a plurality of piezoelectric elements having oscillation frequencies that are different from each other;
a plurality of switching sections provided at both a signal input side and a signal output side of each of the plurality of piezoelectric elements for synchronously selecting any one of the plurality of piezoelectric elements;
a positive feedback oscillation loop circuit oscillating one of the plurality of piezoelectric elements selected with the plurality of switching sections; and
a plurality of impedance elements each provided to a respective one of the plurality of piezoelectric elements and adjusting a frequency variation of the respective one of the plurality of piezoelectric elements with respect to a control voltage.

16. A frequency selective oscillator, comprising:
a plurality of piezoelectric elements having oscillation frequencies that are different from each other;
a plurality of switching sections provided at both an input side and an output side of each of the plurality of piezoelectric elements for synchronously selecting any one of the plurality of piezoelectric elements;
a positive feedback oscillation loop circuit oscillating one of the plurality of piezoelectric elements selected with the plurality of switching sections; and
a plurality of capacitors each provided to a respective one of the plurality of piezoelectric elements and adjusting a variation of the frequency variation of the respective one of the plurality of piezoelectric elements with respect to a control voltage.

17. The frequency selective oscillator according to claim 16, wherein
the positive feedback oscillation loop includes a tank circuit,
a second capacitor adjusting a variation of the frequency variation is disposed between the plurality of switching sections at the output side of the plurality of piezoelectric elements and the tank circuit, and is connected in parallel to the tank circuit.

18. The frequency selective oscillator according to claim 16, wherein
each of the plurality of piezoelectric elements comprises a surface acoustic wave resonator.

19. An electronic instrument, comprising
a frequency selective oscillator, including:
a plurality of piezoelectric elements having oscillation frequencies that are different from each other;
a plurality of switching sections provided at both an input side and an output side of each of the plurality of piezoelectric elements for synchronously selecting either one of the plurality of piezoelectric elements;
a positive feedback oscillation loop circuit oscillating one of the plurality of piezoelectric elements selected with the plurality of switching sections; and
a plurality of capacitors each provided to a respective one of the plurality of piezoelectric elements and adjusting a frequency variation of the respective one of the plurality of piezoelectric elements with respect to a control voltage.

20. A method of adjusting a frequency control characteristic, comprising:
comparing a frequency variation of one of a plurality of piezoelectric elements implemented in a frequency selective oscillator with respect to a control voltage applied to the plurality of piezoelectric elements with a frequency variation of another of the plurality of piezoelectric elements; and
varying a capacitance of a plurality of capacitors each connected to a respective one of the plurality of piezoelectric elements in accordance with a variation of the frequency variations with respect to the control voltage so that the frequency variations among the plurality of piezoelectric elements are adjusted within a predetermined range of a reference frequency variation.
